(19) United States
(12) Patent Application Publication
(10) Pub. No.: US 2019/0103588 A1
(43) Pub. Date: Apr. 4, 2019

(54) OLED, METHOD FOR MANUFACTURING THE SAME, DISPLAY SUBSTRATE AND DISPLAY DEVICE

(71) Applicant: BOE TECHNOLOGY GROUP CO., LTD., Beijing (CN)

(72) Inventors: Bo Jiang, Beijing (CN); Wei Huang, Beijing (CN)

(21) Appl. No.: 16/129,270

(22) Filed: Sep. 12, 2018

(30) Foreign Application Priority Data
Sep. 30, 2017 (CN) 201710927692.8

(51) Int. Cl. H01L 51/52; H01L 51/56

(52) U.S. Cl. CPC H01L 51/5275; H01L 51/5218; H01L 2251/5315; H01L 51/56; H01L 2251/558; H01L 51/5234

(57) ABSTRACT

Embodiments of the present disclosure provide an OLED, a method for manufacturing the same, a display substrate and a display device. The OLED includes: a reflective electrode, an organic light-emitting layer, a translucent electrode, and a light extraction layer located on a side of the translucent electrode away from the organic light-emitting layer and being in contact with the translucent electrode, which are arranged in sequence, wherein the light extraction layer is of a single layer structure and has a refractive index that decreases along a light-emitting direction, the light-emitting direction is a direction of the light extraction layer away from the organic light-emitting layer, and wherein a refractive index of the light extraction layer on a side in contact with the translucent electrode is greater than the refractive index of the translucent electrode.

### CROSS-REFERENCE TO RELATED APPLICATION

This application claims priority to Chinese Patent Application No. 201710927692.8 filed on Sep. 30, 2017, the disclosures of which are incorporated in their entirety by reference herein.

### BACKGROUND

The present disclosure relates to the field of display technology, and specifically to an organic light-emitting diode (OLED), a method for manufacturing the same, a display substrate, and a display device.

OLED displays have been widely used in various electronic devices, including computers, mobile phones, and other electronic products, due to their advantages of self-illumination, light weight, low power consumption, high contrast ratio, high color range, the realization of flexible display, etc.

A light-emitting device in an OLED display device includes a first electrode, a second electrode, and an organic functional layer located between the first electrode and the second electrode. The first electrode is a reflective electrode, and the second electrode is a transparent electrode or a translucent electrode.

In the case where the second electrode is a translucent electrode, the transmittance of the translucent electrode is generally less than 70% and the reflectance is relatively high, so that the light-emitting device forms a strong microcavity effect, resulting in limitations to the light output efficiency and the viewing angle of the OLED device.

### SUMMARY

In one aspect, embodiments of the present disclosure provide an OLED including: a reflective electrode, an organic light-emitting layer, a translucent electrode, and a light extraction layer located on a side of the translucent electrode away from the organic light-emitting layer and being in contact with the translucent electrode, which are arranged in sequence, wherein the light extraction layer is of a single layer structure and has a refractive index that decreases along a light-emitting direction, the light-emitting direction is a direction of the light extraction layer away from the organic light-emitting layer, wherein the refractive index of the light extraction layer on a side in contact with the translucent electrode is greater than the refractive index of the translucent electrode.

Optionally, a difference between the refractive index of the light extraction layer on the side in contact with the translucent electrode and the refractive index of the light extraction layer on the side away from the translucent electrode is greater than or equal to 0.1.

Further optionally, the light extraction layer is made of at least two materials having different refractive indices.

Further optionally, the light extraction layer is divided into at least two refractive zones and a transition zone between two adjacent refractive zones in a thickness direction, and the refractive indices of the at least two refractive zones are decreased along the light-emitting direction, wherein one of the refractive zones is mainly made of one material, and the transition zone is mainly made of a mixture of materials of the two adjacent refractive zones.

Further optionally, densities of materials of the at least two refractive zones decreases along the light-emitting direction.

Further optionally, the light extraction layer includes, in the thickness direction, a first refractive index material whose content decreases along the light-emitting direction and a second refractive index material whose content increases along the light-emitting direction, wherein a refractive index of the first refractive index material is greater than a refractive index of the second refractive index material.

Further optionally, a density of the first refractive index material is greater than a density of the second refractive index material.

Further optionally, the first refractive index material having a greater refractive index is one of ZnSe (2.58), TeO₂ (2.41), ZnS (2.36), and ZnO (2.01), and the second refractive index material having a smaller refractive index is one of MoO₃ (1.90), NPB (1.80), MgO (1.73), Alq3 (1.71), BCP (1.71), LiF (1.39), and MgF₂ (1.38).

Further optionally, the OLED further includes at least one single layer film located between the organic light-emitting layer and the translucent electrode and having a refractive index that decreases along the light-emitting direction.

Further optionally, a thickness of the light extraction layer is from 20 nm to 500 nm.

In another aspect, embodiments of the present disclosure further provide an OLED display substrate, including a substrate and the above OLED arranged on the substrate.

Optionally, the translucent electrode in the OLED is located on a side of the reflective electrode away from the substrate.

In a still another aspect, embodiments of the present disclosure further provide an OLED display device, including the above OLED display substrate.

In a still further aspect, embodiments of the present disclosure further provide a method for manufacturing an OLED, including: forming a reflective electrode on a substrate; forming an organic light-emitting layer on the substrate on which the reflective electrode is formed; forming a translucent electrode on the substrate on which the organic light-emitting layer is formed; and forming a light extraction layer on the substrate on which the translucent electrode is formed, wherein the light extraction layer is of a single layer structure and has a refractive index that decreases along a light-emitting direction, and the light-emitting direction is a direction of the light extraction layer away from the organic light-emitting layer, and a refractive index of the light extraction layer on a side in contact with the translucent electrode is greater than the refractive index of the translucent electrode.

Further optionally, the forming the light extraction layer on the substrate on which the translucent electrode is formed includes: printing an inkjet printing ink on the substrate on which the translucent electrode is formed, to form the light extraction layer being of the single layer structure and having a refractive index that decreases along the light-emitting direction. The inkjet printing ink includes two or more inkjet printing materials having different refractive indices, wherein any two of the two or more inkjet printing materials having different refractive indices are a first inkjet printing material and a second inkjet printing material, respectively, and wherein a density of the first inkjet printing material is greater than a density of the second inkjet printing material, and a refractive index of the first inkjet printing material is greater than a refractive index of the second inkjet printing material.

Further optionally, the forming the light extraction layer on the substrate on which the translucent electrode is formed includes: on the substrate on which the translucent electrode is formed, depositing a first evaporation material in a decreasing deposition rate through evaporation and depositing a second evaporation material in an increasing deposition rate through evaporation, to form the light extraction layer being of the single layer structure and having a refractive index that decreases along the light-emitting direction, wherein a refractive index of the first evaporation material is greater than a refractive index of the second evaporation material.

Further optionally, the forming the light extraction layer on the substrate on which the translucent electrode is formed includes: on the substrate on which the translucent electrode is formed, depositing a first evaporation material in a constant deposition rate through evaporation, depositing a second evaporation material in a decreasing deposition rate through evaporation, and/or depositing a third evaporation material in an increasing deposition rate through evaporation, wherein a refractive index of the second evaporation material is greater than a refractive index of the first evaporation material, and a refractive index of the third evaporation material is less than the refractive index of the first evaporation material.

Embodiments of the present disclosure provide an OLED, a display substrate, and a display device. The OLED includes: a reflective electrode, an organic light-emitting layer, a translucent electrode, and a light extraction layer located on a side of the translucent electrode away from the organic light-emitting layer and being in contact with the translucent electrode, which are arranged in sequence, wherein the light extraction layer is of a single layer structure and has a refractive index that decreases along a light-emitting direction, and the light-emitting direction is a direction of the light extraction layer away from the organic light-emitting layer, wherein the refractive index of the light extraction layer on a side in contact with the translucent electrode is greater than the refractive index of the translucent electrode.

### BRIEF DESCRIPTION OF THE DRAWINGS

In order to illustrate the technical solutions of the present disclosure or prior art in a clearer manner, the drawings desired for the present disclosure or prior art will be illustrated hereinafter briefly. Obviously, the following drawings merely relate to some embodiments of the present disclosure. Based on these drawings, a person skilled in the art may obtain the other drawings without any creative effort.

FIG. 1 is a schematic diagram of an OLED according to one embodiment of the present disclosure.

FIG. 2 is a schematic diagram of a light extraction layer according to one embodiment of the present disclosure.

FIG. 3 is a schematic diagram of a light extraction layer according to another embodiment of the present disclosure.

FIG. 4 is a flow chart of a method for manufacturing an OLED according to one embodiment of the present disclosure.

FIG. 5 is a schematic diagram of a light extraction layer formed by vacuum evaporation according to one embodiment of the present disclosure.

### DETAILED DESCRIPTION

The technical solutions in the embodiments of the present disclosure will be described hereinafter in conjunction with the drawings in the embodiments of the present disclosure in a clear and complete manner. Obviously, the following embodiments merely relate to a part of, rather than all of, the embodiments of the present disclosure. Based on these embodiments, a person skilled in the art may, without any creative effort, obtain the other embodiments, which also fall within the scope of the present disclosure.

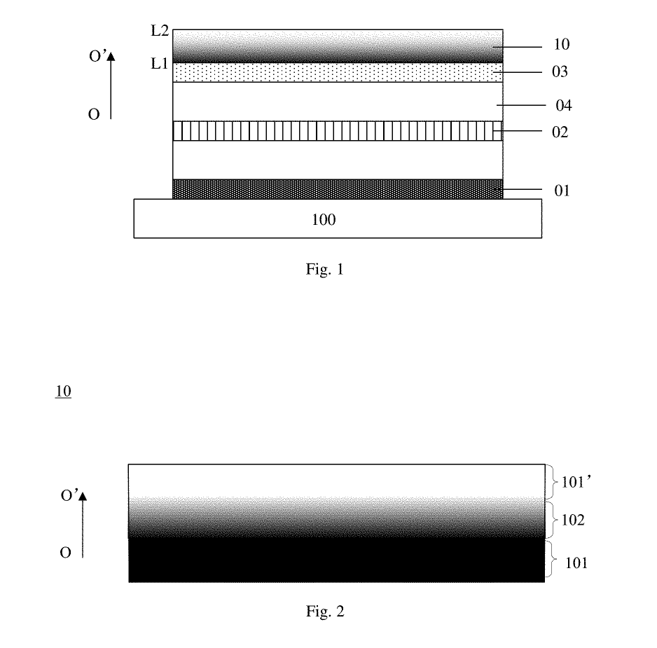

Embodiments of the present disclosure provide an OLED. As shown in FIG. 1, the OLED includes a reflective electrode 01, an organic light-emitting layer 02 and a translucent electrode 03 are arranged in sequence.

Of course, a person skilled in the art would understand that in addition to the above-mentioned reflective electrode, organic light-emitting layer and translucent electrode, the OLED further includes an electron injection layer, an electron transport layer, a hole transport layer, a hole injection layer, etc.; and that one of the reflective electrode and the translucent electrode is used as an anode, and the other is used as a cathode. For ease of description, the following embodiments further illustrate the present disclosure by taking the case as an example where the reflective electrode may be an anode and the translucent electrode may be a cathode.

On this basis, as shown in FIG. 1, the OLED further includes a light extraction layer 10 located on a side of the translucent electrode 03 away from the organic light-emitting layer 02 and being in contact with the translucent electrode 03. The light extraction layer 10 is of a single layer structure and has a refractive index that decreases along a light-emitting direction O-O′. The light-emitting direction O-O′ is a direction of the light extraction layer 10 away from the organic light-emitting layer 02, and a refractive index of the light extraction layer 10 on a side in contact with the translucent electrode 03 is greater than the refractive index of the translucent electrode 03.

Based on this, in the present disclosure, in one aspect, an arrangement, in which a refractive index of the light extraction layer on a side in contact with the translucent electrode is greater than the refractive index of the translucent electrode, is capable of increasing a light-emitting efficiency in a forward direction. In another aspect, an arrangement, in which a refractive index of the light extraction layer decreases along the light-emitting direction, is capable of regulating a wide-angle interference and a multi-beam interference, thereby increasing a light extraction rate of the OLED device and broadening a viewing angle at the same time. In a further aspect, as compared with the light extraction layer, in which a multilayer structure whose refractive index that decreases stepwise is adopted and thus light when passing through the light extraction layer will cause a light energy loss due to the interface between the layers, while the light extraction layer in the present disclosure adopts a single layer structure whose refractive index decreases along a light-emitting direction, that is, the light extraction layer does not have an interlayer interface having a different refractive index along the light-emitting direction, thereby preventing light when passes through the light extraction layer from causing a light energy loss due to the interface between the layers, and thus further increasing the light extraction rate of the OLED device.

It should be noted that the light extraction layer 10 being of a single layer structure and having a refractive index that decreases along a light-emitting direction O-O′ means that the refractive index of the light extraction layer 10 decreases along the light-emitting direction O-O′, but there is no interface between the different refractive index zones.

On this basis, since the refractive index of the light extraction layer is gradually changed, the light extraction layer needs to be made of at least two materials having different refractive indices in practice.

It should be noted here that the refractive index of the material made for the light extraction layer is generally between 1.3 and 2.6. The material made for the light extraction layer may be an inorganic compound, e.g., an inorganic material having a relatively high refractive index, such as ZnO, ZnS, ZnSe, TeO₂, WO₃, MoO₃, MgO, or LiF, but is not limited to these inorganic compounds. The material made for the light extraction layer may be an organic compound, e.g., an organic material having a relatively high refractive index, such as Alq3, Liq3, MeO-TPD, or BCP, but is not limited to these organic compounds. Of course, in actual use, the two materials selected may be the above two inorganic compounds, two organic compounds, or one inorganic compound and one organic compound, and the present disclosure does not have any limitation to this.

The specific arrangement of the light extraction layer made of at least two materials having different refractive indices will be further described below.

One schematic setting manner of the light extraction layer 10 is shown as follows:

For example, as shown in FIG. 2, the light extraction layer 10 is divided into at least two refractive zones and a transition zone 102 between two adjacent refractive zones 101 and 101′ in a thickness direction, and the refractive indices of the at least two refractive zones are decreased along the light-emitting direction O-O′, in which the refractive zone 101′ is located on a side (i.e., the light-emitting side) of the refractive zone 101 away from the translucent electrode, and a refractive index of the refractive zone 101′ is less than a refractive index of the refractive zone 101. Of course, FIG. 2 is exemplified by only adopting two refractive zones 101 and 101′, however, in practice, three or more refractive zones may be adopted, and the present disclosure does not have any limitation to this. The following embodiments further illustrate the present disclosure by taking the case as an example where two refractive zones 101 and 101′ are adopted.

On this basis, one refractive zone (101 or 101′) is mainly made of one material. The transition zone 102 is mainly made of a mixture of materials of two adjacent refractive zones (101 and 101′). That is, the refractive zone 101 is made of a material having a refractive index n1, and the refractive zone 101′ is made of a material having a refractive index n2 (n2<n1), and the transition zone 102 is made of a mixture of the material having a refractive index n1 and the material having a refractive index n2.

It may be understood that the light extraction layer 10 in the present disclosure is of a single layer structure, the above zones are only artificially divided, and in practice, there is no interface between the zones. Of course, the following embodiments will provide a specific method for achieving a light extraction layer being of the single layer structure.

In addition, it should also be understood that for the refractive index distribution in the light extraction layer 10, there is a uniform refractive index (n1 or n2) in the refractive zone (101 or 101′) made of one material. The refractive index of the transition zone 102 gradually transitions from the refractive index n1 of one adjacent the refractive zones 101 to the refractive index n2 of the other adjacent refractive zone 101′.

Further, as for the materials for the different refractive zones in the light extraction layer being of the single layer structure described above, the present disclosure optionally adopts the following arrangement, in which densities of materials of the at least two refractive zones whose refractive indices decrease along the light-emitting direction O-O′ decrease along the light-emitting direction O-O′, that is, any two of the at least two materials made for the above at least two refractive zones are a first refractive index material and a second refractive index material, respectively. If a refractive index of the first refractive index material is greater than a refractive index of the second refractive index material, a density of the first refractive index material will be greater than a density of the second refractive index material. In other words, the greater the refractive index (i.e., the greater the refractive index of the material used) is, the greater the density of the material is.

In this way, when the light extraction layer is formed in practice, based on that the density of the material having a greater refractive index is greater and the density of the material having a smaller refractive index is smaller, the principle of free precipitation may be applied, thereby forming different refractive zones satisfying the foregoing conditions according to materials with different densities having different sedimentation rate, and at the same time, the two materials are in a mixed state between adjacent two refractive zones, and thus a transition zone of the foregoing refractive index transition is formed. Of course, the actual manufacture may refer to the specific manufacture methods and processes provided by the following embodiments.

Another schematic arrangement manner of the light extraction layer 10 is shown as follows:

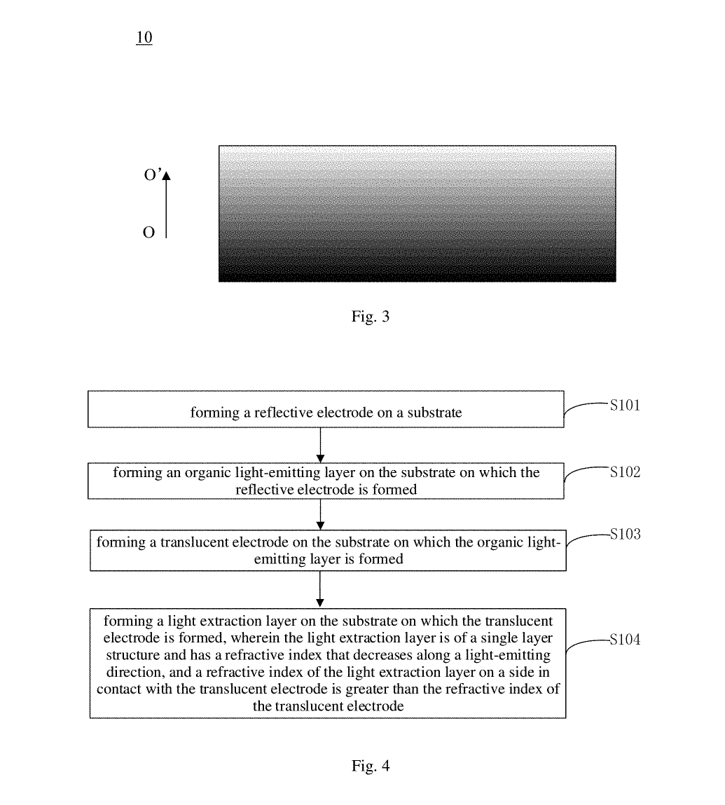

For example, the light extraction layer 10 includes, in the thickness direction, a first refractive index material whose content decreases along the light-emitting direction O-O′ and a second refractive index material whose content increases along the light-emitting direction O-O′. A refractive index of the first refractive index material is greater than a refractive index of the second refractive index material, thereby forming a light extraction layer with a single layer structure whose refractive index as a whole gradually decreases along the light-emitting direction, as shown in FIG. 3 (schematically representing the refractive index in terms of brightness and darkness). Of course, the following embodiments will provide a specific method for achieving a light extraction layer having the single layer structure.

Schematically, the first refractive index material having a greater refractive index is one of ZnSe (2.58), TeO₂ (2.41), ZnS (2.36), and ZnO (2.01), and the second refractive index material having a smaller refractive index is one of MoO₃ (1.90), N,N′-bis(1-naphthyl)-N,N′-diphenyl-1,1′-biphenyl-4,4′-diamine (NPB) (1.80), MgO (1.73), aluminum 8-hydroxyquinoline (Alq3) (1.71), 2,9-dimethyl-4,7-biphenyl-1,10-phenanthroline (BCP) (1.71), LiF (1.39), and MgF₂ (1.38).

It should be noted that the contents of the above first and second refractive index materials may be presented in a percentage by weight.

It should be understood here that in the light extraction layer 10, the content of the first refractive index material having a greater refractive index gradually decreases successively along the light-emitting direction O-O′, and the content of the second refractive index material having a smaller refractive index gradually increases successively along the light-emitting direction O-O′. That is to say, the light extraction layer is of a single layer structure as a whole, and the content of the material having a large refractive index is less and less and the content of the material having a small refractive index is more and more along the light-emitting direction, so that the refractive index of the light extraction layer having the single layer structure as a whole decreases successively along the light-emitting direction.

In summary, for any of the above light extraction layers 10, the present disclosure is optionally referred to FIG. 1. The difference between the refractive index of the light extraction layer 10 on a side L1 in contact with the translucent electrode and a refractive index of the light extraction layer on a side L2 away from the translucent electrode 03 is greater than or equal to 0.1. It should of course be understood that the refractive index of the light extraction layer 10 on the side L2 away from the translucent electrode 03 is necessarily greater than the refractive index of the air.

Specifically, in the case where the difference between the refractive index N1 of the light extraction layer 10 on the side in contact with the translucent electrode 03 and the refractive index N2 of the light extraction layer 10 on the side L2 away from the translucent electrode 03 is less than 0.1, that is, in the case where 0<N1−N2<0.1, the difference in refractive index between the two sides is too small, and thus the level of regulating wide-angle interference and multi-beam interference is small, so that there are limitations to the increase in the light extraction rate and the viewing angle of the OLED device. Therefore, the present disclosure optionally adopts the following arrangement, in which the difference between the refractive index of the light extraction layer 10 on a side L1 in contact with the translucent electrode and a refractive index of the light extraction layer on a side L2 away from the translucent electrode 03 is greater than or equal to 0.1.

On this basis, the present disclosure optionally adopts the following arrangement, in which a thickness of the light extraction layer is from 20 nm to 500 nm.

Specifically, if the thickness of the light extraction layer is less than 20 nm, the thickness is too small (and the above condition of a decreasing refractive index is also required), so that the requirement to the manufacturing process is relatively high, and the wide-angle interference and multi-beam interference are not obvious. If the thickness of the light extraction layer is greater than 500 nm, the thickness is too large, so that this may cause unnecessary waste on one hand, and be adverse to the design concept of lighting and thinning on the other hand. Therefore, the present disclosure optionally adopts the following arrangement, in which the thickness of the extraction layer is in a range from 20 nm to 500 nm, and may of course include 20 nm and 500 nm.

In addition, a person skilled in the art should understand that in order to ensure as much as possible that the light extraction layer is capable of regulating wide-angle interference and multi-beam interference, one in practice needs to choose a reasonable light extraction layer thickness within the above optional thickness range according to the actual light beam (for example, wavelength) and the refractive index range of the light extraction layer.

Further optionally, the OLED may further include at least one single layer film 04 between the organic light-emitting layer 02 and the translucent electrode 03 and having a refractive index that decreases along the light-emitting direction. For example, the film 04 may be an electron transport layer and/or an electron injection layer (in the case where the transparent electrode is a cathode), or may be a hole transport layer and/or a hole injection layer (in the case where the transparent electrode is an anode). Of course, it is also possible to separately arrange other films according to actual needs, and the present disclosure does not have any limitation to this.

In this way, by arranging a single layer film 04 whose refractive index decreases along the light-emitting direction between the organic light-emitting layer 02 and the translucent electrode 03, it is possible to further regulate a wide-angle interference and a multi-beam interference, thereby increasing a light extraction rate of the OLED device and broadening a viewing angle at the same time. Similarly, since the film 04 whose refractive index decreases along the light-emitting direction is of a single layer structure, it is possible to prevent light when passing through the light extraction layer will cause a light energy loss due to the interface between the layers, and thus even further increasing the light extraction rate of the OLED device.

Embodiments of the present disclosure further provide an OLED display substrate, including a substrate and the foregoing OLED arranged on the substrate, and having the same structures and advantageous effects as the OLED provided by the foregoing embodiments. Since the structures and beneficial effects of the OLED have been described in detail in the foregoing embodiments, they are not described herein again.

It should be noted that the above substrate generally refers to a substrate including an array (TFT Array) of thin film transistors (TFT).

On this basis, optionally, the translucent electrode in the OLED of the above display substrate is located on a side of the reflective electrode away from the substrate, that is, the display substrate is of a top emission type, and the light emitted by the OLED device is emitted from the top, thereby being not affected by the arrangement of thin film transistors (TFT) on the substrate, and thus ensuring a high aperture ratio of the device. At the same time, for a given material composition, the operating voltage of the top emitting device may be effectively reduced, thereby extending the service life of the entire device.

In another aspect, embodiments of the present disclosure further provide an OLED display device, including the foregoing OLED display substrate, and also having the same structures and advantageous effects as the OLED provided by the foregoing embodiments. Since the structures and beneficial effects of the OLED have been described in detail in the foregoing embodiments, they are not described herein again.

It should be noted that, in the embodiments of the present disclosure, the above display device may specifically include at least an organic light-emitting diode display panel. The display device may be a display, an electronic paper, a television, a digital photo frame, a mobile phone, a tablet, a navigator, or any product or component having a display function.

Embodiments of the present disclosure further provide a method for manufacturing an OLED. As shown in FIG. 4, the method includes (refer to FIG. 1):

step S101: forming a reflective electrode 01 on the substrate 100;

step S102: forming an organic light-emitting layer 02 on the substrate 100 on which the reflective electrode 01 is formed;

step S103: forming a translucent electrode 03 on the substrate 100 on which the organic light-emitting layer 02 is formed; and

step S104: forming a light extraction layer 10 on the substrate 100 on which the translucent electrode 03 is formed,

In the step S101, the substrate may be a rigid substrate or a flexible substrate, and the present disclosure does not have any limitation to this.

In step S103, the translucent electrode 03 is generally made of a metal or a metal alloy, and may be manufactured by a mild vacuum evaporation method.

In step S104, the light extraction layer 10 is of a single layer structure and has a refractive index that decreases along a light-emitting direction, in which the light-emitting direction O-O′ is a direction of the light extraction layer 10 away from the organic light-emitting layer 02, and a refractive index of the light extraction layer 10 on a side in contact with the translucent electrode 03 is greater than the refractive index of the translucent electrode 03.

It should be understood that the above steps are only of a relative sequential relationship, and are not necessarily two adjacent manufacturing steps, that is, in the actual production, there is also a step for preparing other film between the above two adjacent steps (for example, between step S101 and step S102, and between step 102 and step S103), which will not be described again.

In summary, in the OLED manufactured by the above manufacture method, in one aspect, an arrangement, in which a refractive index of the light extraction layer on a side in contact with the translucent electrode is greater than the refractive index of the translucent electrode, is capable of increasing a light-emitting efficiency in a forward direction. In another aspect, an arrangement, in which a refractive index of the light extraction layer tends to decrease, is capable of regulating a wide-angle interference and a multi-beam interference, thereby increasing a light extraction rate of the OLED device and broadening a viewing angle at the same time. In a yet aspect, as compared with the light extraction layer, in which a multilayer structure whose refractive index decreases stepwise is adopted and thus light when passing through the light extraction layer will cause a light energy loss due to the interface between the layers, the light extraction layer in the present disclosure adopts a single layer structure whose refractive index decreases along a light-emitting direction, that is, the light extraction layer does not have an interlayer interface having a different refractive index along the light-emitting direction, thereby preventing light when passing through the light extraction layer from causing a light energy loss due to the interface between the layers, and thus further increasing the light extraction rate of the OLED device.

The manufacturing manner for forming the light extraction layer 10 on the substrate 100 on which the translucent electrode 03 is formed in the foregoing step S104 will be further described below.

Schematically, the manufacturing manner for forming the light extraction layer 10 on the substrate 100 on which the translucent electrode 03 is formed is shown as follows:

An inkjet printing ink may be printed on the substrate 100 on which the translucent electrode 03 is formed, to form a single layer structure of light extraction layer 10 whose refractive index decreases along a light-emitting direction.

The inkjet printing ink includes two or more inkjet printing materials having different refractive indices. Any two of the two or more inkjet printing materials having different refractive indices are a first inkjet printing material and a second inkjet printing material, respectively. A density of the first inkjet printing material is greater than a density of the second inkjet printing material, and a refractive index of the first inkjet printing material is greater than a refractive index of the second inkjet printing material. That is, the greater the refractive index of the inkjet printing material is, the greater the density is; and the smaller the refractive index of the inkjet printing material is, the smaller the density is.

In this way, since the density of the inkjet printing material having a greater refractive index in the inkjet printing ink is greater and the density of the inkjet printing material having a smaller refractive index is smaller, the principle of free precipitation is applied, and thus the sedimentation rate of the material having a greater refractive index will be greater than the sedimentation rate of the material having a smaller refractive index, thereby forming at least two refractive zones whose refractive indices decrease along the light-emitting direction. Of course, the refractive zone is mainly made of a material having one density (refractive index), and in the physical process of free sedimentation, a transition zone made of a mixture of the materials of two adjacent refractive zones will be formed between the two adjacent refractive zones. The refractive index of the transition zone gradually transitions from the refractive index of one of the adjacent refractive zones to the refractive index of the other of the adjacent refractive zones, and there is no interface in the adjacent position.

Schematically, the manufacturing manner for forming the light extraction layer 10 on the substrate 100 on which the translucent electrode 03 is formed is shown as follows:

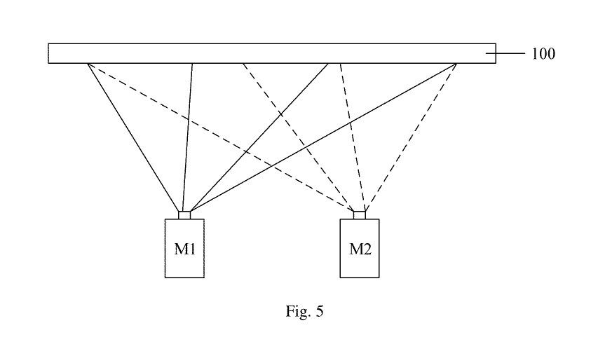

As shown in FIG. 5, on the substrate 100 on which the translucent electrode 03 is formed, depositing a first evaporation material M1 in a decreasing deposition rate through evaporation and depositing a second evaporation material M2 in an increasing deposition rate through evaporation are performed, to form the light extraction layer being of a single layer structure and having a refractive index that decreases, in which a refractive index of the first evaporation material M1 is greater than a refractive index of the second evaporation material M2.

In this way, in the light extraction layer 10 formed, the content (a percentage by weight) of the first evaporation material M1 having a greater refractive index gradually decreases successively in the thickness direction, and the content of the second evaporation material M2 having a smaller refractive index gradually increases successively in the thickness direction. That is to say, the light extraction layer is of a single layer structure as a whole, and the content of the material having a large refractive index is less and less and the content of the material having a small refractive index is more and more along the light-emitting direction, so that the refractive index of the light extraction layer being of the single layer structure as a whole tends to decrease successively along the light-emitting direction.

It should be noted that, firstly, the above depositing the first evaporation material M1 in the decreasing deposition rate through evaporation means that the deposition rate may decrease to zero or may decrease to non-zero, and the present disclosure does not have any limitation to this. The above depositing the second evaporation material M2 in the increasing deposition rate through evaporation means that the deposition rate may increase from zero or may increase from non-zero, and the present disclosure does not have any limitation to this.

Secondly, the above embodiments are exemplified by using two evaporation materials. In practice, more than two evaporation materials may be used, for example, three or four evaporation materials may be used, it should be ensured that various evaporation materials should include, at least: one first evaporation material M1 vapor deposited in an increasing vapor deposition rate, one second evaporation material M2 deposited in a decreasing vapor deposition rate through evaporation; and other evaporation materials may be deposited in a constant vapor deposition rate through evaporation, to ensure that each of the other evaporation materials has the same content at any position in the entire light extraction layer, thereby achieving the adjustment to the refractive index of the entire light extraction layer without affecting the change tendency of the refractive index.

Of course, for the evaporation material deposited at a constant vapor deposition rate through evaporation, the refractive index thereof may be any refractive index. For example, the refractive index may be greater than the refractive index of the first evaporation material M1, thereby increasing the refractive index of the light extraction layer as a whole. For another example, the refractive index may be less than the refractive index of the second evaporation material M2, thereby decreasing the refractive index of the light extraction layer as a whole, and the present disclosure does not have any limitation to this.

Of course, the above embodiments are only illustrative examples. In practice, the actual evaporation rate of each evaporation material may be adjusted according to the need. For example, several vapor deposition manners are provided below:

Specifically, for example, on the substrate 100 on which the translucent electrode 03 is formed, depositing a first evaporation material M1 in a constant deposition rate through evaporation and depositing a second evaporation material M2 in an decreasing deposition rate through evaporation may be performed, in which a refractive index of the second evaporation material M2 is greater than the refractive index of the first evaporation material M1.

In this way, in the light extraction layer, the content of the second evaporation material M2 having a greater refractive index gradually decreases successively in the thickness direction, and the content of the first evaporation material M1 having a smaller refractive index gradually increases successively in the thickness direction. That is to say, the light extraction layer is of a single layer structure as a whole, and the content of the material having a large refractive index is less and less and the content of the material having a small refractive index is more and more along the light-emitting direction, so that the refractive index of the light extraction layer being of the single layer structure as a whole tends to decrease successively along the light-emitting direction.

Further, for example, on the substrate on which the translucent electrode 03 is formed, depositing the first evaporation material M1 in a constant deposition rate through evaporation and depositing a third evaporation material M3 in an increasing deposition rate through evaporation may also be performed, in which a refractive index of the third evaporation material M3 is smaller than the refractive index of the first evaporation material M1.

In this way, in the light extraction layer, the content of the first evaporation material M1 having a greater refractive index gradually decreases successively in the thickness direction, and the content of the third evaporation material M3 having a smaller refractive index gradually increases successively in the thickness direction. That is to say, the light extraction layer is of a single layer structure as a whole, and the content of the material having a large refractive index is less and less and the content of the material having a small refractive index is more and more along the light-emitting direction, so that the refractive index of the light extraction layer being of the single layer structure as a whole decreases successively along the light-emitting direction.

In the present disclosure, in one aspect, an arrangement of the light extraction layer, in which the refractive index on the light incident side is greater than the refractive index of the translucent electrode is capable of increasing a light extraction efficiency in a forward direction. In another aspect, an arrangement, in which a refractive index of the light extraction layer tends to decrease, is capable of regulating a wide-angle interference and a multi-beam interference, thereby increasing a light extraction rate of the OLED device and broadening a viewing angle at the same time. In a yet aspect, as compared with the light extraction layer, in which a multilayer structure whose refractive index decreases stepwise is adopted and thus light when passing through the light extraction layer will cause a light energy loss due to the interface between the layers, the light extraction layer in the present disclosure adopts a single layer structure whose refractive index decreases along a light-emitting direction, that is, the light extraction layer does not have an interlayer interface having a different refractive index along the light-emitting direction, thereby preventing light when passing through the light extraction layer from causing a light energy loss due to the interface between the layers, and thus further increasing the light extraction rate of the OLED device.

The above description is merely the specific embodiment of the present disclosure, but the scope of the present disclosure is not limited thereto. Moreover, any person skilled in the art would readily conceive of modifications or substitutions within the technical scope of the present disclosure, and these modifications or substitutions shall also fall within the protection scope of the present disclosure. Therefore, the protection scope of the present disclosure should be determined by the scope of the claims.

1. An organic light-emitting diode (OLED) comprising:
a reflective electrode;
an organic light-emitting layer;
a translucent electrode; and
a light extraction layer located on a side of the translucent electrode away from the organic light-emitting layer, and in contact with the translucent electrode,
wherein the reflective electrode, the organic light-emitting layer, the translucent electrode, and the light extraction layer are arranged in sequence,
wherein the light extraction layer is of a single layer structure and has a refractive index that decreases along a light-emitting direction, the light-emitting direction is a direction of the light extraction layer away from the organic light-emitting layer, and
wherein the refractive index of the light extraction layer on a side in contact with the translucent electrode is greater than the refractive index of the translucent electrode.

2. The OLED of claim 1, wherein a difference between the refractive index of the light extraction layer on the side in contact with the translucent electrode and the refractive index of the light extraction layer on a side away from the translucent electrode is greater than or equal to 0.1.

3. The OLED of claim 1, wherein the light extraction layer is made of at least two materials having different refractive indices.

4. The OLED of claim 3, wherein the light extraction layer is divided into at least two refractive zones and a transition zone between two adjacent refractive zones in a thickness direction, the refractive indices of the at least two refractive zones are decreased along the light-emitting direction,
wherein one of the refractive zones is mainly made of one material, and the transition zone is mainly made of a mixture of materials of the two adjacent refractive zones.

5. The OLED of claim 4, wherein densities of materials of the at least two refractive zones decrease along the light-emitting direction.

6. The OLED of claim 3, wherein the light extraction layer is made of, in a thickness direction, a first refractive index material whose content decreases along the light-emitting direction and a second refractive index material whose content increases along the light-emitting direction, wherein a refractive index of the first refractive index material is greater than a refractive index of the second refractive index material.

7. The OLED of claim 6, wherein a density of the first refractive index material is greater than a density of the second refractive index material.

8. The OLED of claim 6, wherein the first refractive index material having a greater refractive index is one of ZnSe (2.58), TeO₂ (2.41), ZnS (2.36), and ZnO (2.01), and the second refractive index material having a smaller refractive index is one of MoO₃ (1.90), NPB (1.80), MgO (1.73), Alq3 (1.71), BCP (1.71), LiF (1.39), and MgF₂ (1.38).

9. The OLED of claim 1, wherein the OLED further comprises at least one single layer film located between the organic light-emitting layer and the translucent electrode and having a refractive index decreasing along the light-emitting direction.

10. The OLED of claim 1, wherein a thickness of the light-extraction layer is from 20 nm to 500 nm.

11. An OLED display substrate, comprising a substrate and the OLED of claim 1 arranged on the substrate.

12. The OLED display substrate of claim 11, wherein the translucent electrode in the OLED is located on a side of the reflective electrode away from the substrate.

13. An OLED display device, comprising the OLED display substrate of claim 11.

14. A method for manufacturing an OLED, comprising:
forming a reflective electrode on a substrate;
forming an organic light-emitting layer on the substrate on which the reflective electrode is formed;
forming a translucent electrode on the substrate on which the organic light-emitting layer is formed; and
forming a light extraction layer on the substrate on which the translucent electrode is formed,
wherein the light extraction layer is of a single layer structure and has a refractive index decreasing along a light-emitting direction, the light-emitting direction is a direction of the light extraction layer away from the organic light-emitting layer, and the refractive index of the light extraction layer on a side in contact with the translucent electrode is greater than the refractive index of the translucent electrode.

15. The method of claim 14, wherein the forming the light extraction layer on the substrate on which the translucent electrode is formed comprises:
printing an inkjet printing ink on the substrate on which the translucent electrode is formed, to form the light extraction layer being of the single layer structure and having a refractive index that decreases along the light-emitting direction, the inkjet printing ink comprising two or more inkjet printing materials having different refractive indices, wherein any two of the two or more inkjet printing materials having different refractive indices are a first inkjet printing material and a second inkjet printing material, respectively, and wherein a density of the first inkjet printing material is greater than a density of the second inkjet printing material, and a refractive index of the first inkjet printing material is greater than a refractive index of the second inkjet printing material.

16. The method of claim 14, wherein the forming the light extraction layer on the substrate on which the translucent electrode is formed comprises:
on the substrate on which the translucent electrode is formed, depositing a first evaporation material in a decreasing deposition rate through evaporation and depositing a second evaporation material in an increasing deposition rate through evaporation, to form the light extraction layer being of the single layer structure and having a refractive index that decreases along the light-emitting direction, wherein a refractive index of the first evaporation material is greater than a refractive index of the second evaporation material.

17. The method of claim 14, wherein the forming the light extraction layer on the substrate on which the translucent electrode is formed comprises:
on the substrate on which the translucent electrode is formed, depositing a first evaporation material in a constant deposition rate through evaporation, depositing a second evaporation material in a decreasing deposition rate through evaporation, and/or depositing a third evaporation material in an increasing deposition rate through evaporation, wherein a refractive index of the second evaporation material is greater than a refractive index of the first evaporation material, and a refractive index of the third evaporation material is less than the refractive index of the first evaporation material.

18. The method of claim 14, wherein a difference between the refractive index of the light extraction layer on the side in contact with the translucent electrode and the refractive index of the light extraction layer on the side away from the translucent electrode is greater than or equal to 0.1.

19. The method of claim 14, wherein the light extraction layer is made of at least two materials having different refractive indices.
